(19) United States
(12) Patent Application Publication
(10) Pub. No.: US 2023/0145862 A1
(43) Pub. Date: May 11, 2023

(54) DISPLAY APPARATUSES, DISPLAY PANELS, AND METHODS OF MANUFACTURING DISPLAY PANELS

(71) Applicants: Chengdu BOE Optoelectronics Technology Co., Ltd., Chengdu, Sichuan (CN); BOE Technology Group Co., Ltd., Beijing (CN)

(72) Inventors: Rong WANG, Beijing (CN); Bo ZHANG, Beijing (CN); Xiaoqing SHU, Beijing (CN); Xiangdan DONG, Beijing (CN); Fan HE, Beijing (CN)

(21) Appl. No.: 17/915,298

(22) PCT Filed: Oct. 26, 2021
(86) PCT No.: PCT/CN2021/126420

§ 371 Date: Sep. 28, 2022

(30) Foreign Application Priority Data
Feb. 22, 2021 (CN) 202110199003.2

(51) Int. Cl. H10K 59/121; H10K 59/122; H10K 59/12

(52) U.S. Cl. CPC H10K 59/1213; H10K 59/122; H10K 59/1201

(57) ABSTRACT

The present disclosure provides a display apparatus, a display panel, and a method of manufacturing a display panel. The display panel includes a base substrate, a conductive layer, an organic insulating structure, a first organic convex ring, and a cathode material layer. A first isolation trench for exposing the conductive layer is provided between the organic insulating structure and the first organic convex ring, and a ratio of a width of the first isolation trench to a maximum allowable fluctuation for a distance between an edge position of the cathode material layer and an edge of the organic insulating structure ranges from 0.025 to 0.218. According to embodiments of the present disclosure, when a distance between an edge of a cathode and an outer edge of a frame area is fixed, the maximum allowable fluctuation for the distance between the edge position of the cathode material layer and the edge of the organic insulating structure may be increased by reducing the width of the first isolation trench. As a result, the cathode material layer may not fall into the first isolation trench in the evaporation process, so as to avoid short circuit due to overlap of the cathode with the conductive layer, thereby improving the yield of the display panel.

### TECHNICAL FIELD

The present disclosure relates to the field of display device technology, and in particular to a display apparatus, a display panel, and a method of manufacturing a display panel.

### BACKGROUND

OLED is a display and lighting technology that has been gradually developed in recent years, especially in the display industry, and is considered to have broad application prospects due to its advantages such as high response, high contrast, and flexibility.

An existing OLED display panel involves multiple processes during a manufacturing process thereof, and some processes have a small process window. If a process deviation is too large, a yield of the display panel may be reduced.

### SUMMARY

The present disclosure provides a display apparatus, a display panel, and a method of manufacturing a display panel, so as to solve the deficiencies in the related art.

To achieve the above objectives, a first aspect of embodiments of the present disclosure provides a display panel, including:

a base substrate, including a display area and a frame area surrounding the display area;

a conductive layer, disposed in the frame area;

an organic insulating structure and a first organic convex ring, disposed on a side of the conductive layer away from the base substrate, with a first isolation trench between the organic insulating structure and the first organic convex ring for exposing the conductive layer; and

a cathode material layer, disposed on a side of the organic insulating structure away from the base substrate, where a ratio of a width of the first isolation trench to a maximum allowable fluctuation for a distance between an edge position of the cathode material layer and an edge of the organic insulating structure ranges from 0.025 to 0.218.

Optionally, the ratio of the width of the first isolation trench to the maximum allowable fluctuation for the distance between the edge position of the cathode material layer and the edge of the organic insulating structure ranges from 0.032 to 0.194.

Optionally, the display panel further includes:

a pixel driving circuit, disposed in the display area and including a transistor; and

a pixel structure, disposed on a side of the pixel driving circuit away from the base substrate and including an anode, where the anode is electrically connected with a first electrode of the transistor through a transfer electrode, the first electrode is one of a source electrode and a drain electrode, and the conductive layer serves as the transfer electrode.

Optionally, the display panel further includes:

a first planarization layer, disposed on a side of the transistor away from the display area and in a portion of the frame area, where the transfer electrode is disposed on a side of the first planarization layer away from the base substrate and in a portion of the frame area that is not covered with the first planarization layer;

a second planarization layer, disposed on sides of the transfer electrode and a portion of the first planarization layer that is not covered with the transfer electrode away from the base substrate, where the anode is disposed on a side of the second planarization layer away from the base substrate; and

a pixel definition layer, disposed on sides of the anode and a portion of the second planarization layer that is not covered with the anode away from the base substrate, and having an opening for exposing the anode, where each of the organic insulating structure and the first organic convex ring is a stacked structure of the second planarization layer and the pixel definition layer.

Optionally, a ratio of a sum of a width of the first organic convex ring and the width of the first isolation trench to the maximum allowable fluctuation for the distance between the edge position of the cathode material layer and the edge of the organic insulating structure ranges from 0.23 to 0.469.

Optionally, the display panel further includes:

a second organic convex ring, disposed on the side of the conductive layer away from the base substrate, with a second isolation trench between the second organic convex ring and the first organic convex ring for exposing the conductive layer, where a ratio of a sum of a width of the second organic convex ring, a width of the second isolation trench, a width of the first organic convex ring and the width of the first isolation trench to the maximum allowable fluctuation for the distance between the edge position of the cathode material layer and the edge of the organic insulating structure ranges from 0.359 to 0.903.

A second aspect of embodiments of the present disclosure provides a display apparatus including the display panel according to any one of the above.

A third aspect of embodiments of the present disclosure provides a method of manufacturing a display panel, including:

providing a base substrate that includes a display area and a frame area surrounding the display area, and forming a conductive layer in the frame area;

forming an organic insulating structure and a first organic convex ring on a side of the conductive layer away from the base substrate, with a first isolation trench between the organic insulating structure and the first organic convex ring for exposing the conductive layer; and

forming a cathode material layer on a side of the organic insulating structure away from the base substrate, and controlling a ratio of a width of the first isolation trench to a maximum allowable fluctuation for a distance between an edge position of the cathode material layer and an edge of the organic insulating structure to range from 0.025 to 0.218.

Optionally, the method further includes: forming a second organic convex ring on the side of the conductive layer away from the base substrate, with a second isolation trench between the second organic convex ring and the first organic convex ring for exposing the conductive layer; and controlling a ratio of a sum of a width of the second organic convex ring, a width of the second isolation trench, a width of the first organic convex ring and the width of the first isolation trench to the maximum allowable fluctuation for the distance between the edge position of the cathode material layer and the edge of the organic insulating structure to range from 0.359 to 0.903.

Optionally, the method further includes:

forming a pixel driving circuit in the display area, the pixel driving circuit including a transistor;

forming a first planarization layer on a side of the pixel driving circuit away from the display area and in a portion of the frame area;

forming a transfer electrode on a side of the first planarization layer away from the base substrate and in a portion of the frame area that is not covered with the first planarization layer, where the transfer electrode is electrically connected with a first electrode of the transistor through a first conductive plug in the first planarization layer, and the first electrode is one of a source electrode and a drain electrode;

forming a second planarization layer on sides of the transfer electrode and a portion of the first planarization layer that is not covered with the transfer electrode, away from the base substrate; and

forming a pixel structure on a side of the second planarization layer away from the base substrate, the pixel structure including an anode, where the anode is electrically connected with the transfer electrode through a second conductive plug in the second planarization layer, and the conductive layer serves as the transfer electrode.

Optionally, forming the pixel structure includes:

forming the anode on the side of the second planarization layer away from the base substrate;

forming a pixel definition layer on sides of the anode and a portion of the second planarization layer that is not covered with the anode away from the base substrate, the pixel definition layer having an opening for exposing the anode; and

forming, in a stacked structure of the second planarization layer and the pixel definition layer, the first isolation trench for exposing the transfer electrode.

Optionally, forming the pixel structure includes:

forming the anode on the side of the second planarization layer away from the base substrate;

forming a pixel definition layer on sides of the anode and a portion of the second planarization layer that is not covered with the anode away from the base substrate, the pixel definition layer having an opening for exposing the anode; and

forming, in a stacked structure of the second planarization layer and the pixel definition layer, the first isolation trench and a second isolation trench for exposing the transfer electrode, the first isolation trench being located close to the display area and the second isolation trench being located away from the display area.

Due to shadow effects, when the cathode material layer is evaporated to form a cathode, the cathode material layer is not only located in the display area, but also falls in the frame area. According to the above embodiments of the present disclosure, the ratio of the width of the first isolation trench to the maximum allowable fluctuation for the distance between the edge position of the cathode material layer and the edge of the organic insulating structure is controlled to range from 0.025 to 0.218 in layout design. When a distance between an edge of the cathode and an outer edge of the frame area is fixed, the maximum allowable fluctuation for the distance between the edge position of the cathode material layer and the edge of the organic insulating structure may be increased by reducing the width of the first isolation trench. As a result, the cathode material layer may not fall into the first isolation trench in the evaporation process, so as to avoid short circuit due to overlap of the cathode with the conductive layer, thereby improving the yield of the display panel.

It should be understood that the foregoing general description and the following detailed description are exemplary and explanatory only, and are not intended to limit the present disclosure.

### BRIEF DESCRIPTION OF THE DRAWINGS

The accompanying drawings herein, which are incorporated into and constitute a part of this specification, illustrate embodiments consistent with the present disclosure, and serve to explain the principles of the present disclosure together with the specification.

FIG. 1 is a schematic diagram illustrating a cross-sectional structure of a display panel according to a first embodiment of the present disclosure.

FIG. 2 is a flow chart illustrating a method of manufacturing a display panel according to a first embodiment of the present disclosure.

FIGS. 3 to 7 are schematic diagrams illustrating intermediate structures corresponding to processes in FIG. 2.

FIG. 8 is a schematic diagram illustrating a cross-sectional structure of a display panel according to a second embodiment of the present disclosure.

List of reference signs

| | |
|---|---|
| display panel 1, 2 | base substrate 10 |
| display area 10a | frame area 10b |
| conductive layer 20 | organic insulating structure 30 |
| first organic convex ring 31 | first isolation trench 32 |
| cathode material layer 401 | pixel structure 40 |
| anode 40a | cathode 40b |
| light-emitting block 40c | transistor T |
| active layer 11 | gate insulation layer 12 |
| gate electrode 13 | source electrode 14a |
| drain electrode 14b | storage capacitor C |
| first electrode plate 21 | second electrode plate 22 |
| first interlayer dielectric layer | second interlayer dielectric layer |
| ILD1 | ILD2 |
| passivation layer PVX | first planarization layer PLN1 |
| transfer electrode 15 | second planarization layer PLN2 |
| pixel definition layer PDL | second organic convex ring 33 |
| second isolation trench 34 | |
| distance between edge of cathode | |
| and outer edge of frame area D | |
| width of first isolation trench W1 | width of first organic convex ring W2 |
| width of second isolation trench | width of second organic convex ring |
| W3 | W4 |
| maximum allowable fluctuation for | |
| distance between edge position of | |
| cathode material layer and edge of | |
| organic insulating structure a | |

### DETAILED DESCRIPTION OF THE EMBODIMENTS

Exemplary embodiments will be described herein in detail, examples of which are illustrated in the drawings. When the following description involves the drawings, like numerals in different drawings refer to like or similar elements unless otherwise indicated. Embodiments described in the following exemplary embodiments do not represent all embodiments consistent with the present disclosure. Rather, they are merely examples of apparatuses and methods consistent with some aspects of the present disclosure as detailed in the appended claims.

FIG. 1 is a schematic diagram illustrating a cross-sectional structure of a display panel according to a first embodiment of the present disclosure.

Referring to FIG. 1, a display panel 1 includes:

a base substrate 10, including a display area 10a and a frame area 10b surrounding the display area 10a;

a conductive layer 20, disposed in the frame area 10b;

an organic insulating structure 30 and a first organic convex ring 31, disposed on a side of the conductive layer 20 away from the base substrate 10, with a first isolation trench 32 between the organic insulating structure 30 and the first organic convex ring 31 for exposing the conductive layer 20; and

a cathode material layer 401, disposed on a side of the organic insulating structure 30 away from the base substrate 10, where a ratio of a width W1 of the first isolation trench 32 to a maximum allowable fluctuation a for a distance between an edge position of the cathode material layer 401 and an edge of the organic insulating structure 30 ranges from 0.025 to 0.218.

In this embodiment, the range includes endpoint values.

The base substrate 10 may be a flexible substrate or a rigid substrate. The flexible substrate may be made of polyimide, and the rigid substrate may be made of glass.

A buffer layer, a vapor barrier layer, etc. may be provided on the polyimide and glass.

A number of pixel structures 40 arranged in an array are provided in the display area 10a. Each pixel structure 40 includes an anode 40a, a cathode 40b, and a light-emitting block 40c disposed between the anode 40a and the cathode 40b. The light-emitting block 40c may be made of OLED. The light-emitting block 40c may be red, green or blue, or may be red, green, blue or yellow. The pixel structures 40 with three primary colors of red, green and blue or four primary colors of red, green, blue and yellow are alternately distributed. The cathodes 40b of the respective pixel structures 40 may be connected together to form a surface electrode.

Referring to FIG. 1, in this embodiment, a pixel driving circuit is provided between the anode 40a and the base substrate 10 and includes a number of transistors, and the anode 40a is electrically connected with a drain electrode 14b of a transistor T. In other words, the pixel structure 40 is an Active Matrix OLED (AMOLED).

AMOLED adopts a transistor array to control each pixel to emit light, and each pixel may emit light continuously.

The pixel driving circuit includes a transistor T and a storage capacitor C. The transistor T may include an active layer 11, a gate insulation layer 12, a gate electrode 13, a source electrode 14a, and the drain electrode 14b.

The storage capacitor C may include a first electrode plate 21, a capacitor dielectric layer, and a second electrode plate 22.

In this embodiment, the active layer 11 is located close to the base substrate 10, while the gate electrode 13 is located away from the base substrate 10, and thus the transistor T has a top-gate structure. The first electrode plate 21 is located on the same layer as the gate electrode 13. A first interlayer dielectric layer ILD1 is provided on sides of the first electrode plate 21 and the gate electrode 13 away from the base substrate 10, and the first interlayer dielectric layer ILD1 serves as the capacitor dielectric layer. The first interlayer dielectric layer ILD1 is disposed on the entire surface of the display area 10a and the frame area 10b. A second interlayer dielectric layer ILD2 is provided on sides of the second electrode plate 22 and a portion of the first interlayer dielectric layer ILD1 that is not covered with the second electrode plate 22 away from the base substrate 10. The source electrode 14a and the drain electrode 14b are disposed on a side of the second interlayer dielectric layer ILD2 away from the base substrate 10. The source electrode 14a may be connected to a source region of the active layer 11 by filling a via hole passing through the first interlayer dielectric layer ILD1 and the second interlayer dielectric layer ILD2. The drain electrode 14b may be connected to a drain region of the active layer 11 by filling a via hole passing through the first interlayer dielectric layer ILD1 and the second interlayer dielectric layer ILD2. The active layer 11 between the source region and the drain region is a channel region.

In other embodiments, the transistor T may have a bottom-gate structure. The specific structure of the pixel driving circuit is not limited in the embodiments of the present disclosure.

With continued reference to FIG. 1, a passivation layer PVX may be provided on sides of the source electrode 14a, the drain electrode 14b, and a portion of the second interlayer dielectric layer ILD2 that is not provided with the source electrode 14a and the drain electrode 14b, away from the base substrate 10. A first planarization layer PLN1 is provided on a side of the passivation layer PVX located in a portion of the frame area 10b and the display area 10a away from the base substrate 10. A transfer electrode 15 is provided on sides of the first planarization layer PLN1 and a portion of the passivation layer PVX that is not covered with the first planarization layer PLN1 away from the base substrate 10. The transfer electrode 15 may extend from the display area 10a to the frame area 10b.

In this embodiment, the transfer electrode 15 is connected to one of the source electrode 14a and the drain electrode 14b by filling a via hole passing through the first planarization layer PLN1. In other embodiments, a first conductive plug may be formed in the first planarization layer PLN1 with one end of the first conductive plug connected to one of the source electrode 14a and the drain electrode 14b, followed by forming the transfer electrode 15 at the other end of the first conductive plug.

A second planarization layer PLN2 is provided on sides of the transfer electrode 15 and the first planarization layer PLN1 away from the base substrate 10.

The pixel structure 40 is provided on a side of the second planarization layer PLN2 away from the base substrate 10. In this embodiment, the anode 40a of the pixel structure 40 is connected to the transfer electrode 15 by filling a via hole passing through the second planarization layer PLN2. In other embodiments, a second conductive plug may be formed in the second planarization layer PLN2 with one end of the second conductive plug connected to the transfer electrode 15, followed by forming the anode 40a at the other end of the second conductive plug.

A pixel definition layer PDL is provided on sides of the anode 40a and a portion of the second planarization layer PLN2 that is not covered with the anode 40a away from the base substrate 10. The pixel definition layer PDL has an opening for exposing a portion of the anode 40a, and the light-emitting block 40c is disposed in the opening. The cathode 40b is disposed on the light-emitting block 40c and the pixel definition layer PDL.

The first planarization layer PLN1, the second planarization layer PLN2, and the pixel definition layer PDL may all be made of an organic insulating material such as polyimide.

In this embodiment, a stacked structure of the pixel definition layer PDL and the second planarization layer PLN2 serves as both the organic insulating structure 30 and the first organic convex ring 31. In other embodiments, the pixel definition layer PDL or the second planarization layer PLN2 located in the frame area 10b may serve as the first organic convex ring 31. The first organic convex ring 31 forms a dam.

In this embodiment, the transfer electrode 15 located in the display area 10a is the conductive layer 20. The transfer electrode 15 may be electrically connected to a power signal VDD or an initialization signal Vinit. In other embodiments, the conductive layer 20 may be a layer with a potential different from that of the cathode 40b of the pixel structure 40 in any operating state.

The cathode material layer 401 is evaporated through a mask, and due to shadow effects, the cathode material layer 401 is not only located in a predetermined area to form the cathode 40b, but also falls in the frame area 10b. To ensure the coverage of the cathode 40b, the predetermined area is generally slightly larger than the display area 10a. In layout design, the ratio of the width W1 of the first isolation trench 32 to the maximum allowable fluctuation a for the distance between the edge position of the cathode material layer 401 and the edge of the organic insulating structure 30 is controlled to range from 0.025 to 0.218. The maximum allowable fluctuation a is the maximum distance that the edge of the organic insulating structure 30 is pushed inward towards the display area 10a, that is, a distance between an edge position of the cathode 40b and the edge of the organic insulating structure 30. When the cathode material layer 401 satisfies the above condition, it is possible to avoid short circuit due to overlap of the cathode 40b with the conductive layer 20. When a distance D between an edge of the cathode 40b and an outer edge of the frame area 10b and a width W2 of the first organic convex ring 31 are fixed, the maximum allowable fluctuation a for the distance between the edge position of the cathode material layer 401 and the edge of the organic insulating structure 30 may be increased by reducing the width W1 of the first isolation trench 32. As a result, the cathode material layer 401 may not fall into the first isolation trench 32, so as to avoid short circuit due to overlap of the cathode 40b with the conductive layer 20, thereby improving the yield of the display panel 1.

In some embodiments, the cathode material layer 401 and the organic insulating structure 30 not covered with the cathode material layer 401, the first organic convex ring 31, and the first isolation trench 32 may be covered with an encapsulation layer on the entire side away from the base substrate. The encapsulation layer may be a thin-film encapsulation layer, including a number of inorganic-organic-inorganic multilayer overlapping structures. The dam formed by the first organic convex ring 31 may prevent overflow of the organic encapsulation layer. The encapsulation layer is in direct contact with the conductive layer 20, which can prevent water and oxygen from the outside from entering the pixel structure 40 located in the display area 10a.

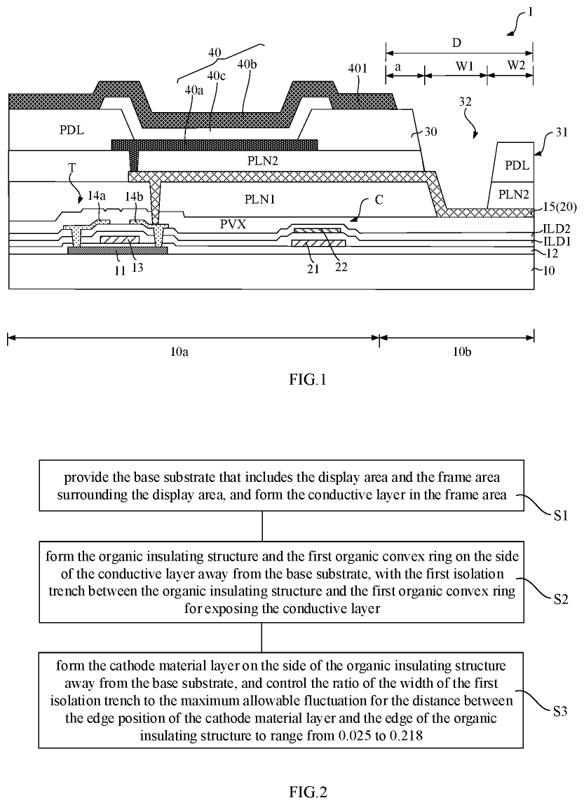

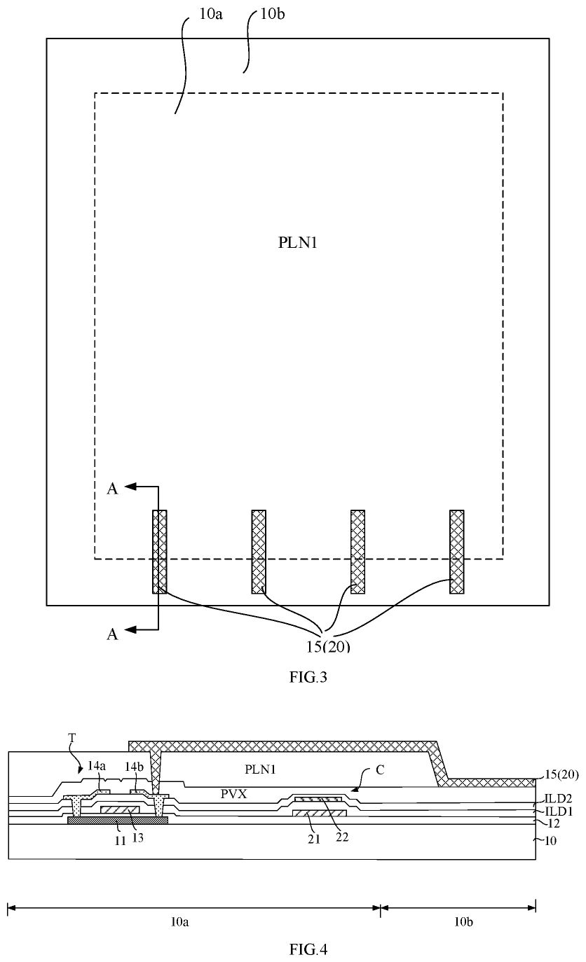

An embodiment of the present disclosure further provides a method of manufacturing the display panel 1 in FIG. 1. FIG. 2 is a flow chart illustrating the method. FIGS. 3 to 7 are schematic diagrams illustrating intermediate structures corresponding to processes in FIG. 2.

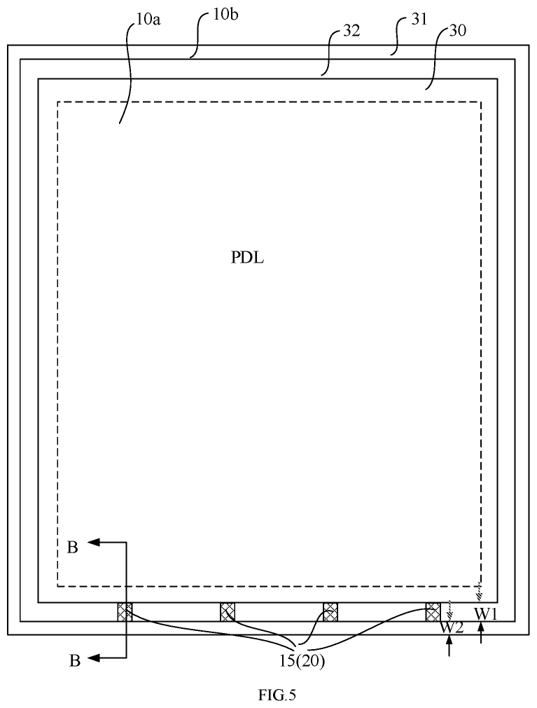

First, referring to step S1 in FIG. 1, FIG. 3, and FIG. 4 which illustrates a cross-sectional view along line AA in FIG. 3, the base substrate 10 is provided, the base substrate 10 including the display area 10a and the frame area 10b surrounding the display area 10a; and the conductive layer 20 is formed in the frame area 10b.

The base substrate 10 may be a flexible substrate or a rigid substrate. The flexible substrate may be made of polyimide, and the rigid substrate may be made of glass.

A buffer layer, a vapor barrier layer, etc. may be provided on the polyimide and glass.

The conductive layer 20 may be a layer with a potential different from that of the cathode 40b of the pixel structure 40 in any operating state. In this embodiment, step S1 may further include steps S11 to S20.

At step S11, an active material layer is formed on the entire surface of the base substrate 10, and the active material layer is patterned to form the active layer 11 in the display area 10a.

At step S12, the gate insulation layer 12 is formed on the entire surfaces of the active layer 11 and the base substrate 10 that is not covered with the active layer 11.

At step S13, a first metal layer is formed on the entire surface of the gate insulation layer 12, and the first metal layer is patterned to form the gate electrode 13 and the first electrode plate 21 in the display area 10a.

At step 514, the first interlayer dielectric layer ILD1 is formed on the entire surfaces of the gate electrode 13, the first electrode plate 21, and the gate insulation layer 12 that is not covered with the gate electrode 13 and the first electrode plate 21.

At step 515, a second metal layer is formed on the entire surface of the first interlayer dielectric layer ILD1, and the second metal layer is patterned to form the second electrode plate 22 in the display area 10a.

At step S16, the second interlayer dielectric layer ILD2 is formed on the entire surfaces of the second electrode plate 22 and the first interlayer dielectric layer ILD1 that is not covered with the second electrode plate 22.

At step 517, via holes are formed in the second interlayer dielectric layer ILD2, the first interlayer dielectric layer ILD1, and the gate insulation layer 12 in the display area 10a, to expose the source and drain regions of the active layer 11, respectively, the via holes are filled, and the source electrode 14a and the drain electrode 14b are formed on the second interlayer dielectric layer ILD2.

At step 518, the passivation layer PVX is formed on the source electrode 14a, the drain electrode 14b, and the second interlayer dielectric layer ILD2 that is not covered with the source electrode 14a and the drain electrode 14b.

At step S19, the first planarization layer PLN1 is formed on the entire surface of the passivation layer PVX, and the first planarization layer PLN1 is patterned, to remove an area of the first planarization layer PLN1 where the first organic convex ring 31 and the first isolation trench 32 are to be formed.

At step S20, a via hole is formed in the first planarization layer PLN1 and the passivation layer PVX in the display area 10a to expose one of the source electrode 14a and the drain electrode 14b, the via hole is filled, and the transfer electrode 15 is formed on the first planarization layer PLN1 and the passivation layer PVX not covered with the first planarization layer PLN1. The transfer electrode 15 extends from the display area 10a to the frame area 10b. In other words, the transfer electrode 15 is the conductive layer 20.

The active layer 11, the gate insulation layer 12, the gate electrode 13, the source electrode 14a, and the drain electrode 14b form the transistor T. The first electrode plate 21, the capacitor dielectric layer, and the second electrode plate 22 form the storage capacitor C. In other embodiments, the transistor T may have a bottom-gate structure. The specific structure of the pixel driving circuit is not limited in the embodiments of the present disclosure.

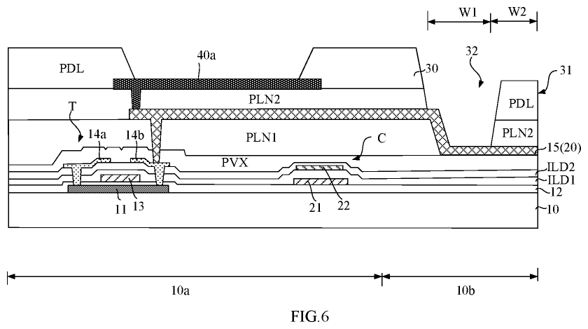

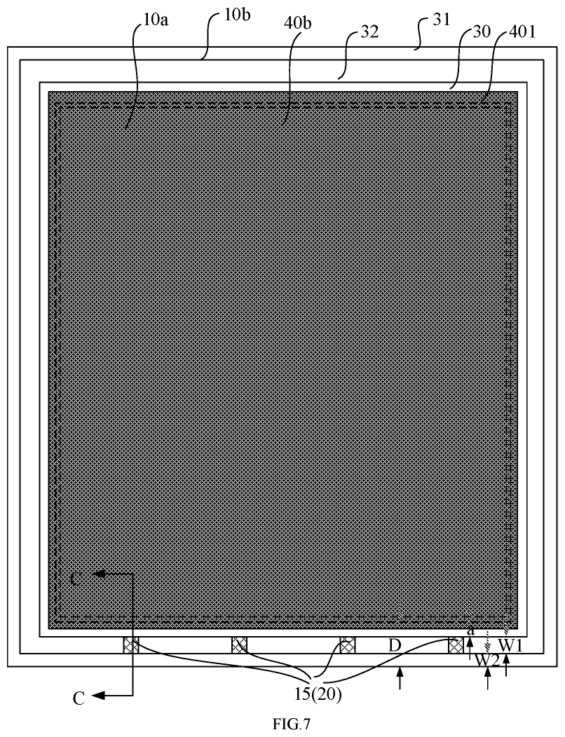

Next, referring to step S2 in FIG. 2, FIG. 5, and FIG. 6 which illustrates a cross-sectional view along line BB in FIG. 5, the organic insulating structure 30 and the first organic convex ring 31 are formed on the side of the conductive layer 20 away from the base substrate 10, with the first isolation trench 32 between the organic insulating structure 30 and the first organic convex ring 31 for exposing the conductive layer 20.

In this embodiment, step S2 may further include steps S21 to S23.

At step S21, the second planarization layer PLN2 is formed on the entire surfaces of the transfer electrode 15 and the first planarization layer PLN1 not covered with the transfer electrode 15, a via hole is formed in the second planarization layer PLN2 in the display area 10a to expose the transfer electrode 15, the via hole is filled, and the anode 40a is formed on the transfer electrode 15.

At step S22, the pixel definition layer PDL is formed on the entire surfaces of the anode 40a and the second planarization layer PLN2 not covered with the anode 40a, and the opening is formed in the pixel definition layer PDL to expose a portion of the anode 40a.

At step S23, the pixel definition layer PDL and the second planarization layer PLN2 are patterned to form the first isolation trench 32 surrounding the display area 10a in the frame area 10b. In other words, the stacked structure of the second planarization layer PLN2 and the pixel definition layer PDL located in the frame area 10b serves as the first organic convex ring 31.

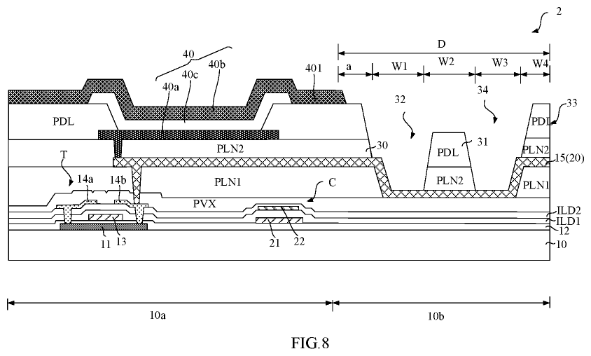

After that, referring to step S3 in FIG. 2, FIG. 7, and FIG. 1 which illustrates a cross-sectional view along line CC in FIG. 7, the cathode material layer 401 is formed on the side of the organic insulating structure 30 away from the base substrate 10, and the ratio of the width W1 of the first isolation trench 32 to the maximum allowable fluctuation a for the distance between the edge position of the cathode material layer 401 and the edge of the organic insulating structure 30 is controlled to range from 0.025 to 0.218.

In this embodiment, step S3 may further include steps S31 and S32.

At step S31, a light-emitting material layer is evaporated to form the light-emitting block 40c in the opening of the pixel definition layer PDL.

At step S32, the cathode material layer 401 is evaporated on the entire surfaces of the light-emitting block 40c and the pixel definition layer PDL by using a mask. The cathode material layer 401 in the display area 10a forms the cathode 40b. Due to shadow effects, when the cathode material layer 401 is evaporated to form the cathode 40b, the cathode material layer 401 is not only located in the display area 10a, but also falls in the frame area 10b.

In layout design, when the distance D between the edge of the cathode 40b and the outer edge of the frame area 10b and the width W2 of the first organic convex ring 31 are fixed, the maximum allowable fluctuation a for the distance between the edge position of the cathode material layer 401 and the edge of the organic insulating structure 30 may be increased by reducing the width W1 of the first isolation trench 32. As a result, the cathode material layer 401 may not fall into the first isolation trench 32 in the evaporation process, so as to avoid short circuit due to overlap of the cathode 40b with the conductive layer 20, thereby improving the yield of the display panel 1.

Further, the ratio of the width W1 of the first isolation trench 32 to the maximum allowable fluctuation a for the distance between the edge position of the cathode material layer 401 and the edge of the organic insulating structure 30 may be controlled to range from 0.032 to 0.194, so as to further ensure that the cathode material layer 401 may not fall into the first isolation trench 32 in the evaporation process.

In other embodiments, in layout design, the width W2 of the first organic convex ring 31 may also be adjusted, such that a ratio of a sum of the width W2 of the first organic convex ring 31 and the width W1 of the first isolation trench 32 to the maximum allowable fluctuation a for the distance between the edge position of the cathode material layer 401 and the edge of the organic insulating structure 30 may range from 0.23 to 0.469. In other words, when the distance D between the edge of the cathode 40b and the outer edge of the frame area 10b is fixed, the maximum allowable fluctuation a for the distance between the edge position of the cathode material layer 401 and the edge of the organic insulating structure 30 may be increased by reducing the sum of the width W1 of the first isolation trench 32 and the width W2 of the first organic convex ring 31.

Further, in layout design, the ratio of the sum of the width W2 of the first organic convex ring 31 and the width W1 of the first isolation trench 32 to the maximum allowable fluctuation a for the distance between the edge position of the cathode material layer 401 and the edge of the organic insulating structure 30 may range from 0.29 to 0.417.

FIG. 8 is a schematic diagram illustrating a cross-sectional structure of a display panel according to a second embodiment of the present disclosure. Referring to FIG. 8, the display panel 2 according to this embodiment has substantially the same structure as the display panel 1 in FIG. 1, except that it further includes a second organic convex ring 33 disposed on the side of the conductive layer 20 away from the base substrate 10, with a second isolation trench 34 between the second organic convex ring 33 and the first organic convex ring 31 for exposing the conductive layer 20. In other words, two organic convex rings are provided.

In other embodiments, three or more organic convex rings may be provided.

In this embodiment, the stacked structure of the second planarization layer PLN2 and the pixel definition layer PDL serves as the second organic convex ring 33. The first planarization layer PLN2, the transfer electrode 15, and the second organic convex ring 33 form an outer dam.

The first organic convex ring 31 forms an inner dam, and thus a height of the outer dam is greater than that of the inner dam.

In other embodiments, the height of the outer dam may be equal to that of the inner dam.

In layout design, a ratio of a sum of a width W4 of the second organic convex ring 33, a width W3 of the second isolation trench 34, the width W2 of the first organic convex ring 31, and the width W1 of the first isolation trench 32 to the maximum allowable fluctuation a for the distance between the edge position of the cathode material layer 401 and the edge of the organic insulating structure 30 may be controlled to range from 0.359 to 0.903. In this embodiment, the range includes endpoint values. When the distance D between the edge of the cathode 40b and the outer edge of the frame area 10b is fixed, the maximum allowable fluctuation a for the distance between the edge position of the cathode material layer 401 and the edge of the organic insulating structure 30 may be increased by reducing the sum of the width W4 of the second organic convex ring 33, the width W3 of the second isolation trench 34, the width W2 of the first organic convex ring 31, and the width W1 of the first isolation trench 32.

Further, in layout design, the ratio of the sum of the width W4 of the second organic convex ring 33, the width W3 of the second isolation trench 34, the width W2 of the first organic convex ring 31, and the width W1 of the first isolation trench 32 to the maximum allowable fluctuation a for the distance between the edge position of the cathode material layer 401 and the edge of the organic insulating structure 30 may be controlled to range from 0.389 to 0.844.

Correspondingly, the method of manufacturing the display panel 2 according to this embodiment differs from the method of manufacturing the display panel 1 in FIG. 1 only in the following.

In step S19, the first planarization layer PLN1 is patterned, to remove an area of the first planarization layer PLN1 where the first organic convex ring 31, the first isolation trench 32, and the second isolation trench 34 are to be formed, and retain an area of the first planarization layer PLN1 where the second organic convex ring 33 is to be formed.

In step S2, the second organic convex ring 33 is also formed on the side of the conductive layer 20 away from the base substrate 10. In detail, at step S23, the pixel definition layer PDL and the second planarization layer PLN2 are patterned, to form the first isolation trench 32 and the second isolation trench 34 surrounding the display area 10a in the frame area 10b.

Based on the above display panels 1 and 2, an embodiment of the present disclosure further provides a display apparatus including any one of the above display panels 1 and 2. The display apparatus may include any product or component with a display function, such as electronic paper, mobile phone, tablet computer, TV set, notebook computer, digital photo frame, and navigator.

It should be noted that, sizes of layers and regions may be exaggerated in the drawings for clarity of illustration. Also, it may be understood that when an element or layer is referred to as being “on” another element or layer, it may be directly on the other element or intervening layers may be present. In addition, it may be understood that when an element or layer is referred to as being “under” another element or layer, it may be directly under the other element, or more than one intervening layer or element may be present. In addition, it may be understood that when a layer or element is referred to as being “between” two layers or elements, it may be the only layer between the two layers or elements, or more than one intervening layer or element may be present. Like reference numerals indicate like elements throughout.

In the present disclosure, terms “first” and “second” are only used for descriptive purposes, and cannot be understood as indicating or implying relative importance.

Other embodiments of the present disclosure may readily occur to those skilled in the art upon consideration of the specification and practice of the disclosure disclosed herein. The present disclosure is intended to cover any modifications, uses, or adaptations thereof that follow the general principles of the present disclosure and include common general knowledge or commonly used technical means in the art that are not disclosed in the present disclosure. The specification and embodiments are to be considered exemplary only, with the true scope and spirit of the present disclosure being indicated by the following claims.

It should be understood that the present disclosure is not limited to the precise structures described above and illustrated in the drawings, and that various modifications and changes may be made without departing from the scope thereof. The scope of the present disclosure is limited only by the appended claims.

1. A display panel, comprising:
a base substrate, comprising a display area and a frame area surrounding the display area;
a conductive layer, disposed in the frame area;
an organic insulating structure and a first organic convex ring, disposed on a side of the conductive layer away from the base substrate, with a first isolation trench between the organic insulating structure and the first organic convex ring for exposing the conductive layer; and
a cathode material layer, disposed on a side of the organic insulating structure away from the base substrate, wherein a ratio of a width of the first isolation trench to a maximum allowable fluctuation for a distance between an edge position of the cathode material layer and an edge of the organic insulating structure ranges from 0.025 to 0.218.

2. The display panel according to claim 1, wherein the ratio of the width of the first isolation trench to the maximum allowable fluctuation for the distance between the edge position of the cathode material layer and the edge of the organic insulating structure ranges from 0.032 to 0.194.

3. The display panel according to claim 1, further comprising:
a pixel driving circuit, disposed in the display area and comprising a transistor; and
a pixel structure, disposed on a side of the pixel driving circuit away from the base substrate and comprising an anode, wherein the anode is electrically connected with a first electrode of the transistor through a transfer electrode, the first electrode is one of a source electrode and a drain electrode, and the conductive layer serves as the transfer electrode.

4. The display panel according to claim 3, further comprising:
a first planarization layer, disposed on a side of the pixel driving circuit away from the base substrate and in a portion of the frame area, wherein the transfer electrode is disposed on a side of the first planarization layer away from the base substrate and in a portion of the frame area that is not covered with the first planarization layer;
a second planarization layer, disposed on sides of the transfer electrode and a portion of the first planarization layer that is not covered with the transfer electrode away from the base substrate, wherein the anode is disposed on a side of the second planarization layer away from the base substrate; and
a pixel definition layer, disposed on sides of the anode and a portion of the second planarization layer that is not covered with the anode away from the base substrate, and having an opening for exposing the anode, wherein each of the organic insulating structure and the first organic convex ring is a stacked structure of the second planarization layer and the pixel definition layer.

5. The display panel according to claim 1, wherein a ratio of a sum of a width of the first organic convex ring and the width of the first isolation trench to the maximum allowable fluctuation for the distance between the edge position of the cathode material layer and the edge of the organic insulating structure ranges from 0.23 to 0.469.

6. The display panel according to claim 1, further comprising:
a second organic convex ring, disposed on the side of the conductive layer away from the base substrate, with a second isolation trench between the second organic convex ring and the first organic convex ring for exposing the conductive layer,
wherein a ratio of a sum of a width of the second organic convex ring, a width of the second isolation trench, a width of the first organic convex ring, and the width of the first isolation trench to the maximum allowable fluctuation for the distance between the edge position of the cathode material layer and the edge of the organic insulating structure ranges from 0.359 to 0.903.

7. A display apparatus, comprising a display panel which comprises:
a base substrate, comprising a display area and a frame area surrounding the display area;
a conductive layer, disposed in the frame area;
an organic insulating structure and a first organic convex ring, disposed on a side of the conductive layer away from the base substrate, with a first isolation trench between the organic insulating structure and the first organic convex ring for exposing the conductive layer; and
a cathode material layer, disposed on a side of the organic insulating structure away from the base substrate, wherein a ratio of a width of the first isolation trench to a maximum allowable fluctuation for a distance between an edge position of the cathode material layer and an edge of the organic insulating structure ranges from 0.025 to 0.218.

8. A method of manufacturing a display panel, comprising:
providing a base substrate that comprises a display area and a frame area surrounding the display area, and forming a conductive layer in the frame area;
forming an organic insulating structure and a first organic convex ring on a side of the conductive layer away from the base substrate, with a first isolation trench between the organic insulating structure and the first organic convex ring for exposing the conductive layer; and
forming a cathode material layer on a side of the organic insulating structure away from the base substrate, and controlling a ratio of a width of the first isolation trench to a maximum allowable fluctuation for a distance between an edge position of the cathode material layer and an edge of the organic insulating structure to range from 0.025 to 0.218.

9. The method according to claim 8, further comprising:
forming a second organic convex ring on the side of the conductive layer away from the base substrate, with a second isolation trench between the second organic convex ring and the first organic convex ring for exposing the conductive layer; and
controlling a ratio of a sum of a width of the second organic convex ring, a width of the second isolation trench, a width of the first organic convex ring, and the width of the first isolation trench to the maximum allowable fluctuation for the distance between the edge position of the cathode material layer and the edge of the organic insulating structure to range from 0.359 to 0.903.

10. The method according to claim 8, further comprising:
forming a pixel driving circuit in the display area, the pixel driving circuit comprising a transistor;
forming a first planarization layer on a side of the pixel driving circuit away from the base substrate and in a portion of the frame area;
forming a transfer electrode on a side of the first planarization layer away from the base substrate and in a portion of the frame area that is not covered with the first planarization layer, wherein the transfer electrode is electrically connected with a first electrode of the transistor through a first conductive plug in the first planarization layer, and the first electrode is one of a source electrode and a drain electrode;
forming a second planarization layer on sides of the transfer electrode and a portion of the first planarization layer that is not covered with the transfer electrode, away from the base substrate; and
forming a pixel structure on a side of the second planarization layer away from the base substrate, the pixel structure comprising an anode, wherein the anode is electrically connected with the transfer electrode through a second conductive plug in the second planarization layer, and the conductive layer serves as the transfer electrode.

11. The method according to claim 10, further comprising:
forming the anode on the side of the second planarization layer away from the base substrate;
forming a pixel definition layer on sides of the anode and a portion of the second planarization layer that is not covered with the anode away from the base substrate, the pixel definition layer having an opening for exposing the anode; and
forming, in a stacked structure of the second planarization layer and the pixel definition layer, the first isolation trench for exposing the transfer electrode.

12. The method according to claim 10, further comprising:
forming the anode on the side of the second planarization layer away from the base substrate;
forming a pixel definition layer on sides of the anode and a portion of the second planarization layer that is not covered with the anode away from the base substrate, the pixel definition layer having an opening for exposing the anode; and
forming, in a stacked structure of the second planarization layer and the pixel definition layer, the first isolation trench and a second isolation trench for exposing the transfer electrode, the first isolation trench being located close to the display area and the second isolation trench being located away from the display area.

13. The display apparatus according to claim 7, wherein the ratio of the width of the first isolation trench to the maximum allowable fluctuation for the distance between the edge position of the cathode material layer and the edge of the organic insulating structure ranges from 0.032 to 0.194.

14. The display apparatus according to claim 7, further comprising:
a pixel driving circuit, disposed in the display area and comprising a transistor; and
a pixel structure, disposed on a side of the pixel driving circuit away from the base substrate and comprising an anode, wherein the anode is electrically connected with a first electrode of the transistor through a transfer electrode, the first electrode is one of a source electrode and a drain electrode, and the conductive layer serves as the transfer electrode.

15. The display apparatus according to claim 14, further comprising:
a first planarization layer, disposed on a side of the pixel driving circuit away from the base substrate and in a portion of the frame area, wherein the transfer electrode is disposed on a side of the first planarization layer away from the base substrate and in a portion of the frame area that is not covered with the first planarization layer;
a second planarization layer, disposed on sides of the transfer electrode and a portion of the first planarization layer that is not covered with the transfer electrode away from the base substrate, wherein the anode is disposed on a side of the second planarization layer away from the base substrate; and
a pixel definition layer, disposed on sides of the anode and a portion of the second planarization layer that is not covered with the anode away from the base substrate, and having an opening for exposing the anode, wherein each of the organic insulating structure and the first organic convex ring is a stacked structure of the second planarization layer and the pixel definition layer.

16. The display apparatus according to claim 7, wherein a ratio of a sum of a width of the first organic convex ring and the width of the first isolation trench to the maximum allowable fluctuation for the distance between the edge position of the cathode material layer and the edge of the organic insulating structure ranges from 0.23 to 0.469.

17. The display apparatus according to claim 7, further comprising:
a second organic convex ring, disposed on the side of the conductive layer away from the base substrate, with a second isolation trench between the second organic convex ring and the first organic convex ring for exposing the conductive layer,
wherein a ratio of a sum of a width of the second organic convex ring, a width of the second isolation trench, a width of the first organic convex ring, and the width of the first isolation trench to the maximum allowable fluctuation for the distance between the edge position of the cathode material layer and the edge of the organic insulating structure ranges from 0.359 to 0.903.

18. The method according to claim 8, wherein the ratio of the width of the first isolation trench to the maximum allowable fluctuation for the distance between the edge position of the cathode material layer and the edge of the organic insulating structure is controlled to range from 0.032 to 0.194.

19. The method according to claim 8, wherein a ratio of a sum of a width of the first organic convex ring and the width of the first isolation trench to the maximum allowable fluctuation for the distance between the edge position of the cathode material layer and the edge of the organic insulating structure is controlled to range from 0.23 to 0.469.
